(19) United States
(12) Patent Application Publication
(10) Pub. No.: US 2014/0002948 A1
(43) Pub. Date: Jan. 2, 2014

(54) MEMS VARIABLE CAPACITOR

(71) Applicant: Korea Advanced Institute of Science & Technology, Daejeon (KR)

(72) Inventors: Jun Bo YOON, Daejeon (KR); Chang Hoon HAN, Daejeon (KR); Dong Hoon CHOI, Daejeon (KR); Hyun Ho YANG, Daejeon (KR)

(21) Appl. No.: 13/926,083

(22) Filed: Jun. 25, 2013

(30) Foreign Application Priority Data
Jun. 27, 2012 (KR) 10-2012-0068856

(51) Int. Cl. B81B 7/02

(52) U.S. Cl. CPC B81B 7/02
USPC 361/281

(57) ABSTRACT

Disclosed is a MEMS variable capacitor including: a first electrode; a second electrode spaced apart from the first electrode; a third electrode floating above the first electrode; and an actuator including a fourth electrode facing the second electrode, a connector connecting the third electrode and the fourth electrode, and a support supporting a portion of the connector, wherein the third electrode and the connector are integrally formed with each other, and wherein a capacitance is changed by applying a voltage to the second electrode and by adjusting a gap between the first electrode and the third electrode.

### BACKGROUND

1. Field

The present invention relates to a MEMS variable capacitor.

2. Description of Related Art

In a mobile communication system, a radio frequency (RF) block is designed to support various frequency bands. In particular, a capacitor used in a filter related directly to the frequency band should be a variable capacitor which has mutually different capacitances for each frequency band.

FIG. 1 is a perspective view showing a general MEMS variable capacitor. FIG. 2 is a perspective view for describing that a capacitance of the MEMS variable capacitor of FIG. 1 is variable.

Referring to FIGS. 1 and 2, the general MEMS variable capacitor has a structure capable of varying the capacitance through the adjustment of a gap between the floating electrode and a fixed electrode by moving a floating electrode in the structure of seesaw, and thereby varying the capacitance.

That is, the MEMS variable capacitor shown in FIGS. 1 and 2 includes a first electrode 1, a second electrode 2 which is spaced apart from the first electrode 1, a third electrode 20 floating above the first electrode 1 and the second electrode 2, fourth electrodes 21 and 22 which are connected to the third electrode 20 through spring structures 23a and 23b, fifth electrodes 11 and 12 which face the fourth electrodes 21 and 22 and are fixed and adjust a gap between the third electrode 20 and the first and second electrodes 1 and 2 by applying a voltage to the fourth electrodes 21 and 22, and thereby varying the capacitance, and support structures 25a and 25b which fix portions of the spring structures 23a and 23b.

Here, the portions of the spring structures 23a and 23b connecting the third electrode 20 and the fourth electrodes 21 and 22 is fixed by the support structures 25a and 25b. Therefore, with respect to the portions of the fixed spring structures 23a and 23b, the areas of the fourth electrodes 21 and 22 approach closely to the fifth electrodes 11 and 12, and the area of the third electrode 20 becomes farther from the first and the second electrodes 1 and 2.

Therefore, when a voltage is applied from the fifth electrodes 11 and 12 to the fourth electrodes 21 and 22, as shown in the state of FIG. 1 and the state of FIG. 2, the third electrode 20 is displaced to rise above the first and the second electrodes 1 and 2 by a seesaw driving, so that a gap between the third electrode 20 and the first and the second electrodes 1 and 2 is increased. In this manner, the MEMS variable capacitor shown in FIGS. 1 and 2 adjusts the gap between the third electrode 20 and the first and the second electrodes 1 and 2, thereby varying the capacitance.

However, the MEMS variable capacitor includes two or four actuators consisting of spring structures and electrodes around the third electrode 20 in order to adjust the stable gap between the third electrode 20 and the first and second electrodes 1 and 2. In the MEMS variable capacitor, a plurality of the actuators should move synchronously with each other for the variable capacitance. The spring structures 23a and 23b of the actuator are connected to the third electrode 20 by the joint springs 26a and 26b. The joint springs 26a and 26b allow the third electrode 20 to stably move up and down by receiving the rotation moment generated by the seesaw movement of the plurality of the actuators.

However, the joint springs 26a and 26b have a relatively higher resistance component and degrade high selectivity (Q).

After the MEMS variable capacitor is manufactured according to the first-set length of the actuator, it is not possible to control the properties of the MEMS variable capacitor, for example, the range of the capacitance, the linearity of the capacitance and the like.

### SUMMARY

One aspect of the present invention is a MEMS variable capacitor including: a first electrode; a second electrode spaced apart from the first electrode; a third electrode floating above the first electrode; and an actuator including a fourth electrode facing the second electrode, a connector connecting the third electrode and the fourth electrode, and a support supporting a portion of the connector. The third electrode and the connector may be integrally formed with each other. A capacitance may be changed by applying a voltage to the second electrode and by adjusting a gap between the first electrode and the third electrode.

When a voltage is applied to the second electrode, the fourth electrode may fall down toward the second electrode, and the third electrode may be displaced to rise above the first electrode by a seesaw driving caused by the support.

The first electrode and the second electrode may be fixed to a substrate.

Another aspect of the present invention is a MEMS variable capacitor including: a first electrode; a second electrode spaced apart from the first electrode; a third electrode located between the first electrode and the second electrode a fourth electrode floating above the first electrode; and an actuator includes a fifth electrode facing the second electrode, a sixth electrode facing the third electrode, a connector connecting the fourth, the fifth and the sixth electrodes to each other, and a support supporting a portion of the connector. When a voltage is applied to at least one of the second electrode and the third electrode, the capacitance may be changed by adjusting a gap between the first electrode and the fourth electrode.

When a voltage is applied to the second electrode, the fifth electrode may fall down toward the second electrode, and the fourth electrode may be displaced to rise above the first electrode by a seesaw driving caused by the support. When a voltage is applied to the third electrode, the sixth electrode may fall down toward the third electrode, and the fourth electrode may fall down toward the first electrode by a seesaw driving caused by the support.

The fourth electrode and the connector may be integrally formed with each other.

The first electrode, the second electrode and the third electrode may be fixed to a substrate.

### BRIEF DESCRIPTION OF THE DRAWINGS

FIG. 1 is a perspective view showing schematically a general MEMS variable capacitor;

FIG. 2 is a perspective view for describing that the capacitance is changed in the MEMS variable capacitor shown in FIG. 1;

FIG. 3 is a schematic conceptual diagram for describing a MEMS variable capacitor according to an embodiment of the present invention;

FIG. 4a is a perspective view showing a concrete example of the MEMS variable capacitor shown in FIG. 3, and FIG. 4b is a perspective view for describing that the capacitance is changed in the MEMS variable capacitor;

FIG. 5 is a schematic conceptual diagram for describing a MEMS variable capacitor according to another embodiment of the present invention;

FIG. 6a is a perspective view showing a concrete example of the MEMS variable capacitor shown in FIG. 5, and FIG. 6b is a perspective view for describing that the capacitance is changed in the MEMS variable capacitor;

FIG. 7 is a graph showing a relationship between a front voltage applied to a third electrode for the purpose of an optimized linearity and the length of an actuator of the MEMS variable capacitor according to the another embodiment of the present invention;

FIG. 8 is a graph showing a relationship between the capacitance and a rear voltage applied to a second electrode in accordance with the change of the front voltage of the third electrode; and

FIG. 9 is a graph showing a relationship between a normalized value of the capacitance and the rear voltage applied to the second electrode in accordance with the change of the front voltage of the third electrode.

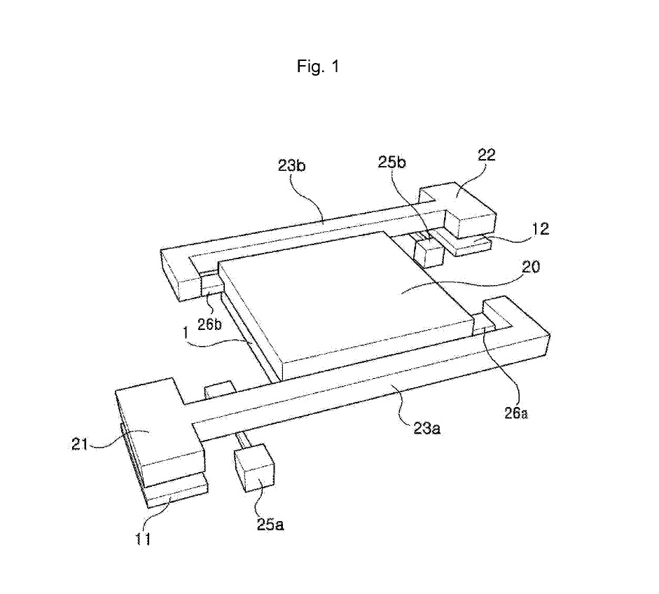

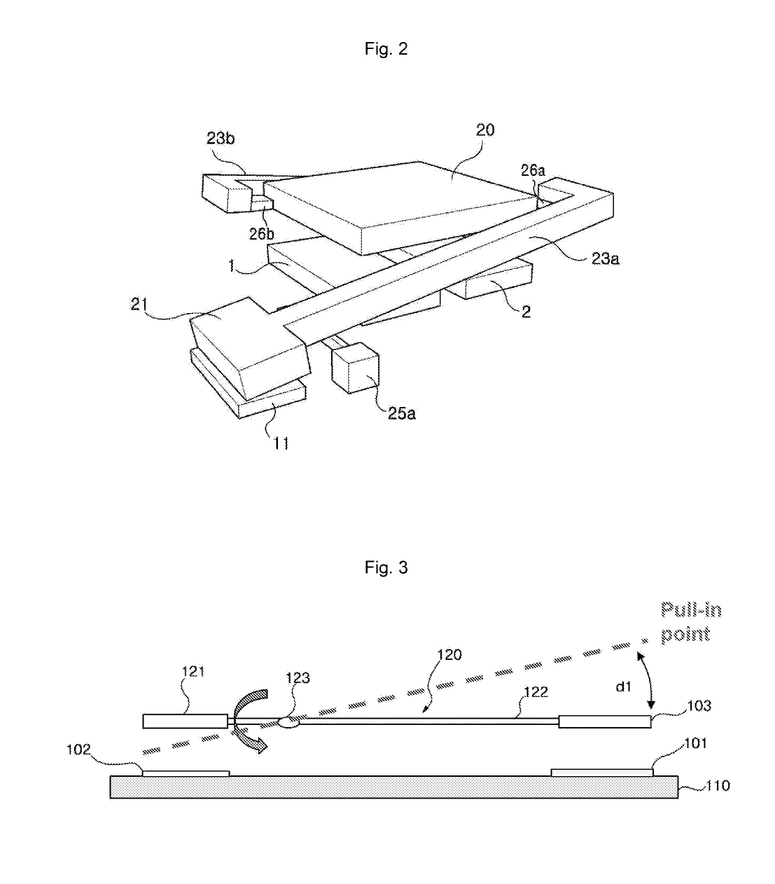

### DETAILED DESCRIPTION

The following detailed description of the present invention shows a specified embodiment of the present invention and will be provided with reference to the accompanying drawings. The embodiment will be described in enough detail that those skilled in the art are able to embody the present invention. It should be understood that various embodiments of the present invention are different from each other and need not be mutually exclusive. For example, a specific shape, structure and properties, which are described in this disclosure, may be implemented in other embodiments without departing from the spirit and scope of the present invention with respect to one embodiment. Also, it should be noted that positions or placements of individual components within each disclosed embodiment may be changed without departing from the spirit and scope of the present invention. Therefore, the following detailed description is not intended to be limited. If adequately described, the scope of the present invention is limited only by the appended claims of the present invention as well as all equivalents thereto. Similar reference numerals in the drawings designate the same or similar functions in many aspects.

Hereafter, a MEMS variable capacitor according to a first embodiment of the present invention will be described.

### First Embodiment

FIG. 3 is a schematic conceptual diagram for describing a MEMS variable capacitor according to an embodiment of the present invention.

Referring to FIG. 3, the MEMS variable capacitor according to the embodiment of the present invention includes a first electrode 101, a second electrode 102 spaced apart from the first electrode 101, a third electrode 103 floating above the first electrode 101, and an actuator 120 controlling the movement of the third electrode 103. The actuator 120 includes a fourth electrode 121 facing the second electrode 102, a connector 122 connecting the third electrode 103 and the fourth electrode 121, and a support 123 supporting a portion of the connector 122. The third electrode 103 and the connector 122 are integrally formed with each other. The capacitance can be changed by applying a voltage to the second electrode 102 and by adjusting a gap between the first electrode 101 and the third electrode 103.

As shown in FIG. 3, in the MEMS variable capacitor according to the embodiment of the present invention, the first electrode 101 and the second electrode 102 are fixed, the third electrode 103 floats above the first electrode 101, and the third electrode 103 is connected to the actuator 120 of which the portion of the connector 122 is supported and operated in the structure of seesaw by the support 123. The connector 122 may be made of a material not transmitting a signal between the third electrode 103 and the fourth electrode 121. For example, the connector 122 may be the spring structure.

As shown in FIG. 3, when a voltage is applied from the second electrode 102 to the fourth electrode 121, the fourth electrode 121 facing the second electrode 102 becomes closer to the second electrode 102, and the third electrode 103 rises above the first electrode 101 as much as a displacement “d1” by a seesaw driving caused by the support 123. Here, the connector 122 and the third electrode 103 are integrally moved. That is, since the joint spring, etc., are not used in the operation of the plurality of the actuators, the connector 122 and the third electrode 103 stably move and the degradation of the selectivity (Q) due to a higher resistance does not occur.

In other words, with the increase of the voltage applied to the second electrode 102, the fourth electrode 121 facing the second electrode 102 becomes closer to the second electrode 102, and the distance between the third electrode 103 and the first electrode 101 is increased. Thus, the capacitance can be changed. Meanwhile, an RF signal is applied to the first electrode 101 and the third electrode 103 and does not flow through the connector 122 connecting the third electrode 103 to the fourth electrode 121. Therefore, the high selectivity (Q) can be obtained.

As shown in FIG. 3, the first electrode 101 and the second electrode 102 may be fixed to one substrate 110. The range in which the capacitance is changed may be changed according to the length between the substrate 110 and the actuator 120.

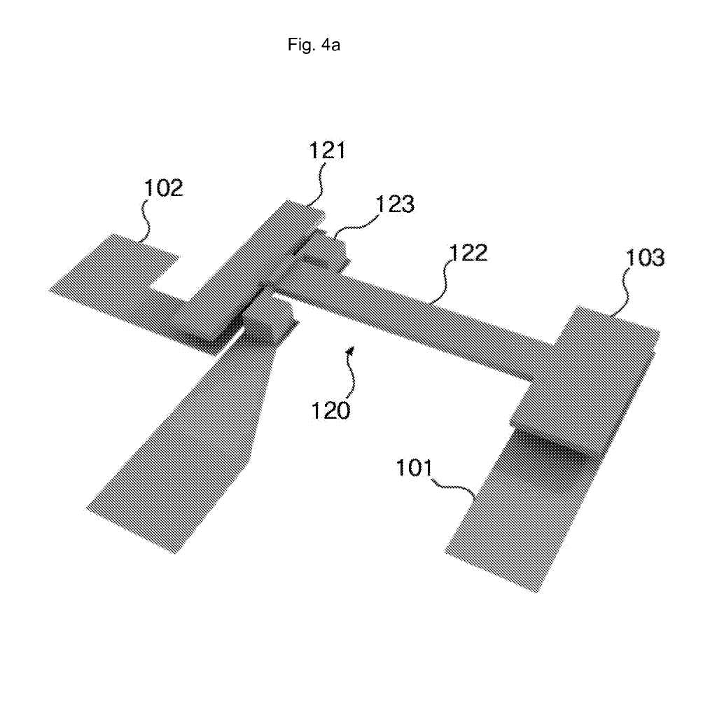

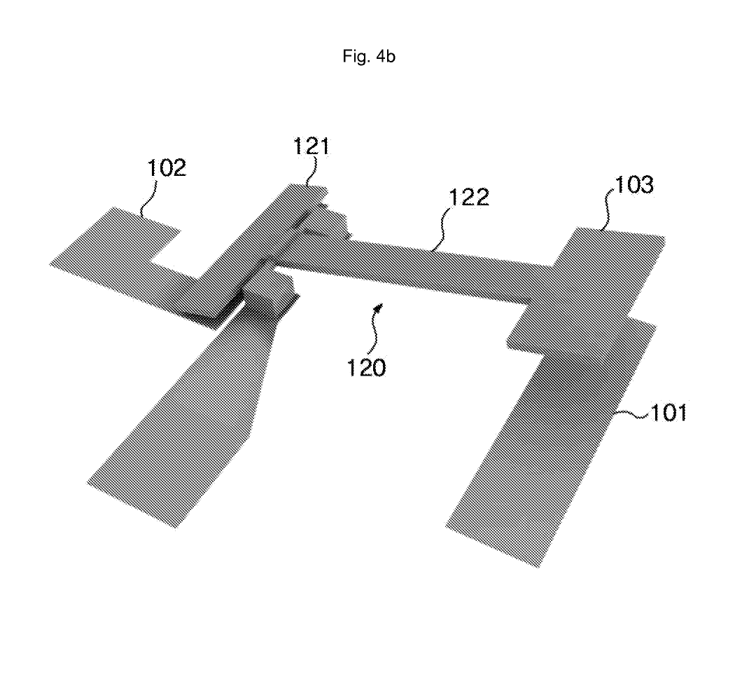

FIG. 4a is a perspective view of the MEMS variable capacitor according to the first embodiment. FIG. 4b is a perspective view showing that the capacitance of the MEMS variable capacitor of FIG. 4a is changed.

Referring to FIGS. 4a and 4b, when a voltage is applied to the second electrode 102, the fourth electrode 121 of the actuator 120 falls down toward the second electrode 102, and the connector 122 and the third electrode 103 connected to the connector 122 rise by the seesaw driving caused by the support 123. Accordingly, the distance between the first electrode 101 and the third electrode 103 is increased, so that the capacitance is changed.

As shown in FIGS. 4a and 4b, the third electrode 103 changing the capacitance may be formed by expanding one end of both ends of the connector 122, which faces the first electrode 101. That is to say, the first electrode 101 and the third electrode 103 function as a capacitor unit for the change of the capacitance, and the third electrode 103 may be formed by transforming the connector 122 of the actuator 120. In other words, the connector 122 and the third electrode 103 may be integrally formed with each other.

As such, unlike a conventional MEMS variable capacitor incapable of easily changing the capacitance due to the fact that the plurality of the actuators do not move synchronously with each other, the MEMS variable capacitor according to the embodiment of the present invention is able to overcome such a problem by using one actuator 120. The size of the MEMS variable capacitor can be reduced by reducing the number of the actuators. Also, since the third electrode 103 and the connector 122 of the actuator 120 are integrally formed with each other, the joint spring is not required. Accordingly, more excellent selectivity (Q) than that of the conventional MEMS variable capacitor can be obtained.

Next, a second embodiment of the present invention will be described.

### Second Embodiment

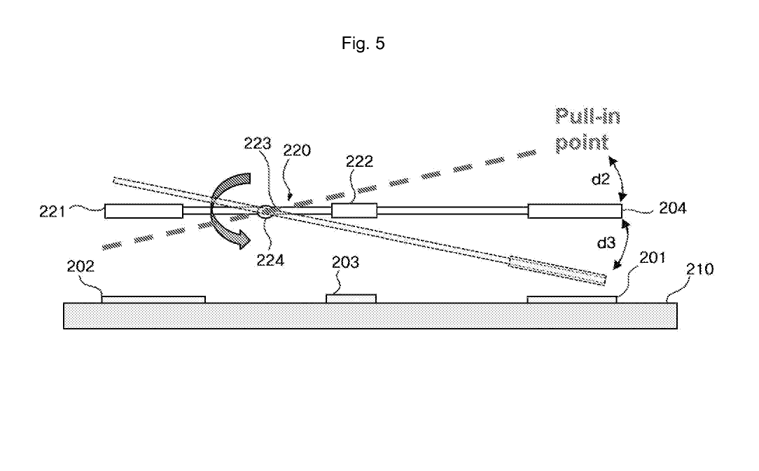

FIG. 5 is a schematic conceptual diagram for describing a MEMS variable capacitor according to a second embodiment.

Referring to FIG. 5, the MEMS variable capacitor according to the second embodiment includes a first electrode 201, a second electrode 202 which is spaced apart from the first electrode 201, a third electrode 203 located between the first electrode 201 and the second electrode 202, a fourth electrode 204 floating above the first electrode 201, and an actuator 220 which controls the movement of the fourth electrode 204. The actuator 220 includes a rear electrode 221 facing the second electrode 202, a front electrode 222 facing the third electrode 203, a connector 223 connecting the rear electrode 221, the front electrode 222 and the fourth electrode 204, and a support 224 supporting a portion of the connector 223. When a voltage is applied to at least one of the second electrode 202 and the third electrode 203, the capacitance can be changed by adjusting a gap between the first electrode 201 and the fourth electrode 204.

The fourth electrode 204 may be integrally formed with the connector 223 of the actuator 220. When the fourth electrode 204 is integrally formed with the connector 223, the joint spring of the conventional MEMS variable capacitor is not required. Accordingly, the selectivity (Q) degradation caused by the high resistance of the joint spring does not occur and manufacturing cost and process time can be reduced.

As shown in FIG. 5, in the MEMS variable capacitor according to the embodiment of the present invention, the first electrode 201, the second electrode 202 and the third electrode 203 are fixed, the fourth electrode 204 floats above the first electrode 201, and the fourth electrode 204 is connected to the actuator 220 of which the portion of the connector 223 is supported and operated in the structure of seesaw by the support 224. It is recommended that the connector 223 should be made of a material not transmitting a signal among the rear electrode 221, the front electrode 222 and the fourth electrode 204.

As shown in FIG. 5, when a voltage is applied from the second electrode 202 to the rear electrode 221, the rear electrode 221 facing the second electrode 202 becomes closer to the second electrode 202, and the fourth electrode 204 rises above the first electrode 201 as much as a displacement “d2” by a seesaw driving caused by the support 224. In the meantime, when a voltage is applied from the third electrode 203 to the front electrode 222, the front electrode 222 facing the third electrode 203 becomes closer to the third electrode 203, and the fourth electrode 204 falls down toward the first electrode 201 as much as a displacement “d3” by the seesaw driving.

In other words, with the increase of the voltage applied to the second electrode 202, the rear electrode 221 facing the second electrode 202 becomes closer to the second electrode 202, and the distance between the fourth electrode 204 and the first electrode 201 is increased. Also, with the increase of the voltage applied to the third electrode 203, the front electrode 222 facing the third electrode 203 becomes closer to the third electrode 203, and the distance between the fourth electrode 204 and the first electrode 201 is decreased. As a result, the capacitance can be changed.

According to the embodiment of the present invention, the first electrode 201, the second electrode 202 and the third electrode 203 may be fixed to one substrate 210.

The more the distance between the actuator 220 and the substrate 210 to which the first electrode 201, the second electrode 202 and the third electrode 203 have been fixed decreases, the more the change rate of the capacitance due to the displacements d2 and d3 of the fourth electrode 204 increases. Therefore, by using a front voltage applied to the third electrode 203, it is easy to obtain the same capacitance tuning ratio as a conventional capacitance tuning ratio by less movement of the actuator 220. Accordingly, the length of the actuator 220 can be reduced and it is possible to obtain more excellent space utilization.

Hereafter, the voltage applied to the second electrode 202 of the MEMS variable capacitor according to the second embodiment is referred to as the rear voltage, and the voltage applied to the third electrode 203 is referred to as the front voltage.

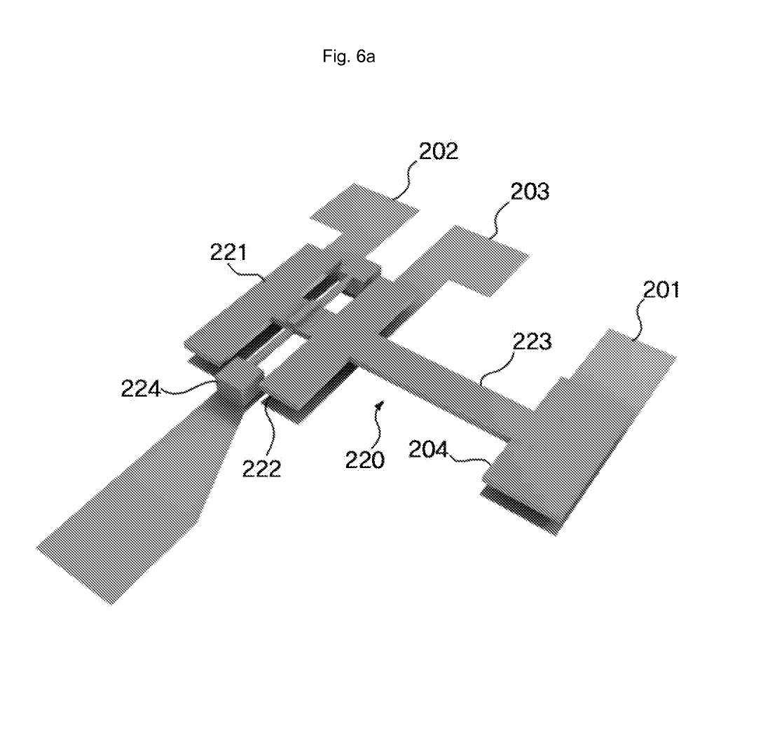

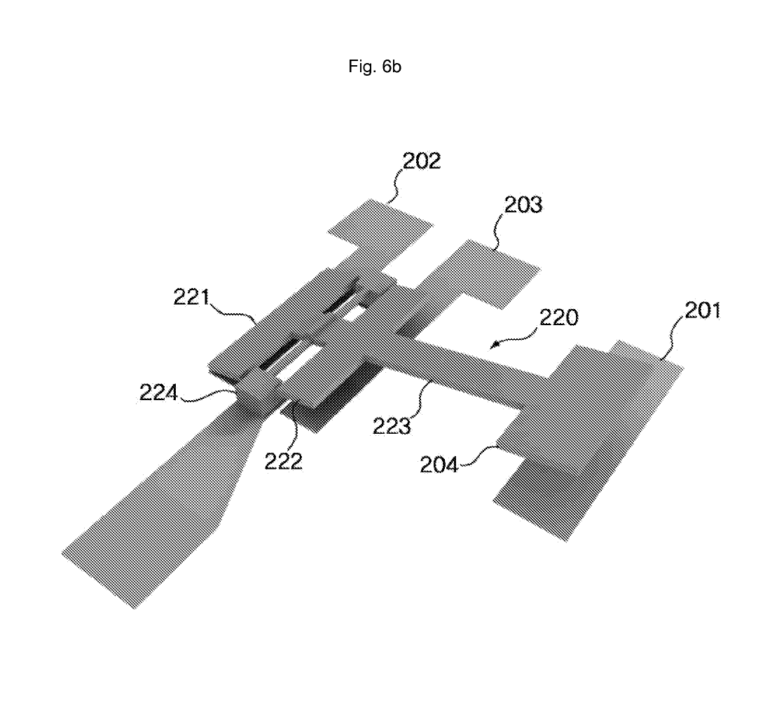

FIG. 6a is a perspective view of the MEMS variable capacitor according to the second embodiment, and FIG. 6b is a perspective view showing that the capacitance of the MEMS variable capacitor is changed.

Referring to FIGS. 6a and 6b, when the voltage is applied to the second electrode 202, the rear electrode 221 of the actuator 220 falls down toward the second electrode 202, and the connector 223 and the fourth electrode 204 connected to the connector 223 rise by the seesaw driving caused by the support 224. Accordingly, the distance between the first electrode 201 and the fourth electrode 204 is increased, so that the capacitance is changed. Also, though not shown in FIGS. 6a and 6b, when the voltage is applied to the third electrode 203, the front electrode 222 of the actuator 220 falls down toward the third electrode 203, and the connector 223 and the fourth electrode 204 connected to the connector 223 fall down by the seesaw driving caused by the support 224. Thus, the capacitance of the MEMS variable capacitor is changed.

Similarly to the first embodiment shown in FIGS. 4a and 4b, in the MEMS variable capacitor shown in FIGS. 6a and 6b, the connector 223 and the fourth electrode 204 may be integrally formed with each other. Since a method and operation thereof for integrally forming them are the same as those of the first embodiment, a detailed description thereof will be omitted.

In the next place, in the MEMS variable capacitor according to the second embodiment, the capacitance change according to the front voltage will be described.

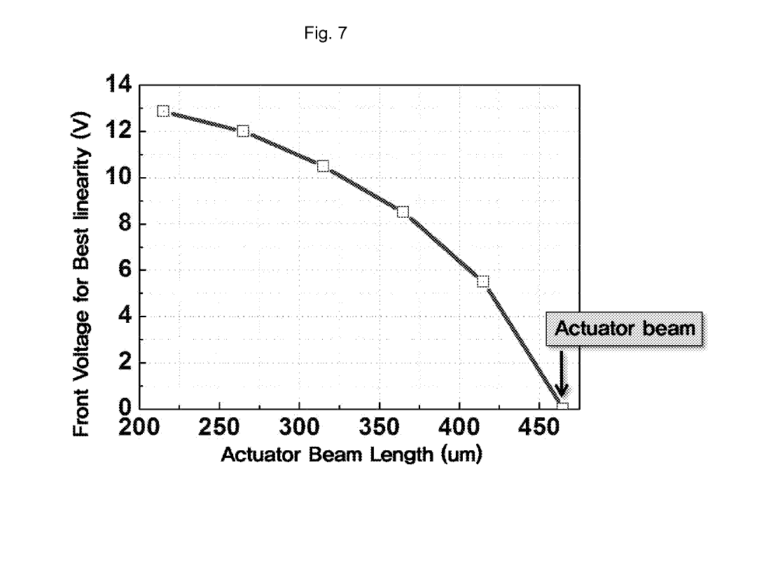

FIG. 7 shows a relationship between the front voltage for obtaining an optimized linearity and the length of the actuator of the MEMS variable capacitor according to the second embodiment of the present invention.

As shown in FIG. 7, it can be seen that the front voltage for maintaining the optimized linearity is increased with the reduction of the length of the actuator. That is, the length of the actuator 220 can be adjusted by controlling the front voltage applied to the third electrode 203. Therefore, when a predetermined front voltage is applied in spite of reducing the length of the actuator 220, the MEMS variable capacitor according to the embodiment of the present invention is capable of maintaining the linearity of the change of the capacitance.

That is to say, the MEMS variable capacitor according to the second embodiment of the present invention is able to obtain the linear capacitance change in accordance with the voltage applied to the second electrode 202.

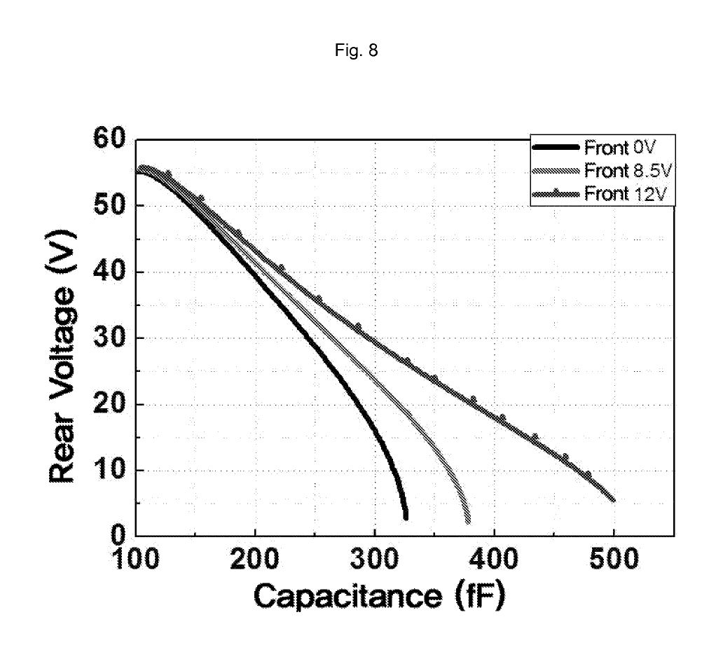

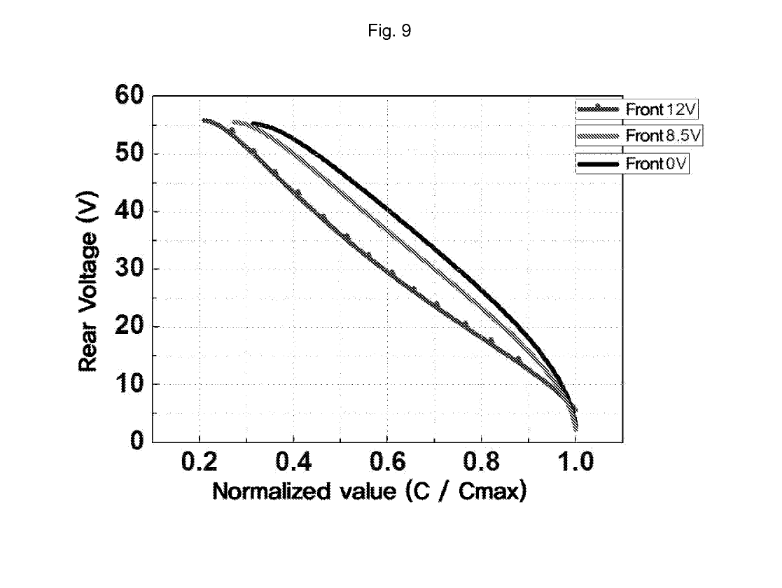

FIGS. 8 and 9 are graphs showing a relationship between the capacitance and the rear voltage applied to the second electrode 202 in accordance with a specific front voltage of the third electrode 203.

As shown in FIGS. 5 and 8, it can be found that when the front voltage applied to the third electrode 203 is changed to 0 V, 8.5 V and 12 V, the amount of the capacitance change based on the rear voltage applied to the second electrode 202 is changed. Therefore, even if the length of the actuator 220 or the distance between the substrate 210 and the actuator 220 is changed, the linearity between the rear voltage and the capacitance change can be maintained by controlling the front voltage.

The linear change between the rear voltage and the capacitance change is effective for controlling the characteristics of a voltage controlled oscillator (VCO) circuit. Specifically, if the capacitance change based on the voltage has a linear relationship in the VCO circuit, it is advantageous for improving the phase noise characteristics of the VCO circuit. The frequency of the output signal of the VCO circuit is changed according to the applied voltage, and thus, in general, the phase noise is changed. However, according to the embodiment of the present invention, since the capacitance change based on the applied voltage is linear, the phase noise of the VCO circuit is maintained constant, so that it is easy to control the phase noise. Accordingly, this is effective for improving the characteristics of the VCO circuit.

Also, through the control of the front voltage, the relationship between the rear voltage and the capacitance can be controlled according to the characteristics of a circuit which uses the MEMS variable capacitor. For example, in order to cause a resonant frequency to be linearly changed according to the applied voltage in an LF filter, the capacitance change based on the applied voltage should be represented not by a straight line graph but by a curved graph. The MEMS variable capacitor according to the embodiment of the present invention is able to control the resonant frequency and the applied voltage of the LC filter to have linearity by controlling the front voltage.

Referring to FIG. 9, it can be understood that the front voltage change causes the relationship between the rear voltage and a normalized value (C/Cmax) of the capacitance to be changed.

In summary, the MEMS variable capacitor according to the embodiment of the present invention raises or moves down the electrodes by using one actuator, and thus, adjusts the capacitance by adjusting the gap between the electrodes. The gap between the electrodes is adjusted by driving the actuator in a seesaw manner, so that the capacitance is adjusted. In other words, the use of the one actuator can overcome a problem caused by the fact that the plurality of the actuators do not move synchronously with each other. Thus, the capacitance can be stably changed. Also, the joint spring is not used between the connector and the electrode, so that the higher selectivity (Q) can be obtained.

As described above, according to the embodiment of the present invention, the MEMS variable capacitor using one actuator can be easily implemented. That is, the size of the actuator for adjusting the capacitance is reduced to make it possible to utilize the space, and the number of the members is reduced to reduce the cost. Also, the capacitance is decreased and increased by applying the front voltage, and thus, the capacitance can be widely changed. Accordingly, it is possible not only to maintain the linearity between the applied voltage and the capacitance change through the capacitance adjustment, but to implement the MEMS variable capacitor having a capacitance relationship with the applied voltage in accordance with the characteristics required by each circuit.

The features, structures and effects and the like described in the embodiments are included in at least one embodiment of the present invention and are not necessarily limited to one embodiment. Furthermore, the features, structures, effects and the like provided in each embodiment can be combined or modified in other embodiments by those skilled in the art to which the embodiments belong. Therefore, contents related to the combination and modification should be construed to be included in the scope of the present invention.

Although embodiments of the present invention were described above, these are just examples and do not limit the present invention. Further, the present invention may be changed and modified in various ways, without departing from the essential features of the present invention, by those skilled in the art. For example, the components described in detail in the embodiments of the present invention may be modified. Further, differences due to the modification and application should be construed as being included in the scope and spirit of the present invention, which is described in the accompanying claims.

What is claimed is:

1. A MEMS variable capacitor comprising:
a first electrode;
a second electrode spaced apart from the first electrode;
a third electrode floating above the first electrode; and
an actuator comprising a fourth electrode facing the second electrode, a connector connecting the third electrode and the fourth electrode, and a support supporting a portion of the connector,
wherein the third electrode and the connector are integrally formed with each other,
and wherein a capacitance is changed by applying a voltage to the second electrode and by adjusting a gap between the first electrode and the third electrode.

2. The MEMS variable capacitor of claim 1, wherein the third electrode is formed by expanding one end of the connector.

3. The MEMS variable capacitor of claim 1, wherein, when a voltage is applied to the second electrode, the fourth electrode falls down toward the second electrode, and the third electrode is displaced to rise above the first electrode by a seesaw driving caused by the support.

4. The MEMS variable capacitor of claim 1, wherein the first electrode and the second electrode are fixed to a substrate.

5. The MEMS variable capacitor of claim 2, wherein the first electrode and the second electrode are fixed to a substrate.

6. The MEMS variable capacitor of claim 3, wherein the first electrode and the second electrode are fixed to a substrate.

7. A MEMS variable capacitor comprising:
a first electrode;
a second electrode spaced apart from the first electrode;
a third electrode located between the first electrode and the second electrode
a fourth electrode floating above the first electrode; and
an actuator includes a fifth electrode facing the second electrode, a sixth electrode facing the third electrode, a connector connecting the fourth, the fifth and the sixth electrodes, and a support supporting a portion of the connector,
wherein, when a voltage is applied to at least one of the second electrode and the third electrode, the capacitance is changed by adjusting a gap between the first electrode and the fourth electrode.

8. The MEMS variable capacitor of claim 7, wherein, when a voltage is applied to the second electrode, the fifth electrode falls down toward the second electrode, and the fourth electrode is displaced to rise above the first electrode by a seesaw driving caused by the support, and wherein, in a case where the support supports the connector located between the fifth electrode and the sixth electrode, when a voltage is applied to the third electrode, the sixth electrode falls down toward the third electrode, and the fourth electrode falls down toward the first electrode by a seesaw driving caused by the support.

9. The MEMS variable capacitor of claim 7, wherein, when a voltage is applied to the second electrode, the fifth electrode falls down toward the second electrode, and the fourth electrode is displaced to rise above the first electrode by a seesaw driving caused by the support, and wherein, in a case where the support supports the connector located between the fourth electrode and the sixth electrode, when a voltage is applied to the third electrode, the sixth electrode falls down toward the third electrode, and the fourth electrode rises above the first electrode by a seesaw driving caused by the support.

10. The MEMS variable capacitor of claim 7, wherein the fourth electrode and the connector are integrally formed with each other.

11. The MEMS variable capacitor of claim 7, wherein the first electrode, the second electrode and the third electrode are fixed to a substrate.

12. The MEMS variable capacitor of claim 8, wherein the first electrode, the second electrode and the third electrode are fixed to a substrate.

13. The MEMS variable capacitor of claim 9, wherein the first electrode, the second electrode and the third electrode are fixed to a substrate.

14. The MEMS variable capacitor of claim 10, wherein the first electrode, the second electrode and the third electrode are fixed to a substrate.
